(19) United States
(12) Patent Application Publication
(10) Pub. No.: US 2003/0047759 A1
(43) Pub. Date: Mar. 13, 2003

(54) Integrated circuit, portable device and method for manufacturing an integrated circuit

(76) Inventors: Joachim Christian Reiner, Kilchberg (CH); Paul Georg Melchior Gradenwitz, Zurich (CH)

Correspondence Address: Michael E. Marion, c/o U.S. PHILIPS CORPORATION, Intellectual Property Department, 580 White Plains Road, Tarrytown, NY, 10591, US

(21) Appl. No.: 10/238,798

(22) Filed: Sep. 10, 2002

(30) Foreign Application Priority Data
Sep. 13, 2001 (EP) 01203460.9

(51) Int. Cl. H01L 27/10

(52) U.S. Cl. 257/204

(57) ABSTRACT

The present invention relates to an integrated circuit, comprising:

a substrate with a first (semi-)conductive region arranged in or on the substrate;

a second (semi-)conductive region which is isolated for at least a considerable part relative to the first region and is arranged above or adjacent to the first region;

a third (semi-)conductive region which is insulated for at least a considerable part relative to the first and second (semi-)conductive regions and is arranged thereabove;

a fourth (semi-)conductive region which is insulated relative to the first, second and third (semi-)conductive regions and is arranged thereabove; and

a (semi-)conductive interconnection contact which mutually connects said four (semi-)conductive regions (semi-)conductively, wherein at least two of the four (semi-)conductive regions extend substantially parallel to the substrate of the integrated circuit at a considerable lateral angle relative to each other.

In portable equipment, such as telephones, dimensions and a low power consumption are of great importance. The functionality of such portable telephones is constantly being increased. In such telephones (working) memory and a microprocessor are usually integrated into a single circuit.

For portable devices such as cellular telephones, organizers and the like, integrated circuits are required with increasing processing power to allow running of more and better software, which requires CMOS (Complementary Metal Oxide Semiconductor) processes with smaller dimensions and higher processing speed. The number of components in a telephone has to be reduced for reasons of cost and size. An important step in reducing the number of components is the integration of a microprocessor and memory on a single chip.

For integrated circuits having only RAM (Random Access memory) cells, techniques are for instance known with special masking steps for the purpose of reducing the surface area required for contacts. Logic products using CMOS lack such possibilities, generally speaking.

It is an object of the present invention to provide a contact and a contacting method for a four layer contact to incorporate a high ohmic layer in standard CMOS processes and to reduce the surface area required for contacts in an integrated circuit which can be produced in CMOS technology.

The present invention provides an integrated circuit, comprising:

a substrate with a first (semi-)conductive region arranged in or on the substrate;

a (semi-)conductive region which is arranged above or adjacent to the first region;

a third (semi-)conductive region which is insulated for at least a considerable part relative to the first and second (semi-)conductive regions and is arranged there above;

a fourth (semi-)conductive region which is insulated relative to the first, second and third (semi-)conductive regions and is arranged thereabove; and

a (semi-)conductive interconnection contact which mutually connects said four (semi-)conductive regions (semi-)conductively, wherein at least two of the four (semi-) conductive regions extend substantially parallel to the substrate of the integrated circuit at a considerable angle relative to each other.

The interconnection contact according to the present invention can connect four layers (semi-) conductively to each other, wherein even in the case of misalignment of the second and the third layer a good edge contact with the interconnection contact and the layer is obtained.

The smallest size for which the approach can be used is highly technology dependent. In a given technology the invention can reduce the area needed for contacts. New technologies have silicide so the contact resistance will be reduced. The approach can be used for silicided and non-silicided technologies.

An integrated circuit can become more compact due to the direct connection of a resistive layer to a contact of one of the FETs. To incorporate such a layer in a CMOS process, a four layer contact is needed to connect an upper metal layer with one diffusion area and two intermediate (semi-)conductive layers. A two layer contact is created by placing a contact plug between the two layers that are above each other. A four layer contact is made by contacting two intermediate layers at the edge. In this case, the upper intermediate layer could mask the lower intermediate layer, thus preventing good edge contact, especially to this layer in case of misalignment.

Further advantages, features and details of the present invention will be elucidated on the basis of the following description of a preferred embodiment thereof with reference to the annexed drawings, in which:

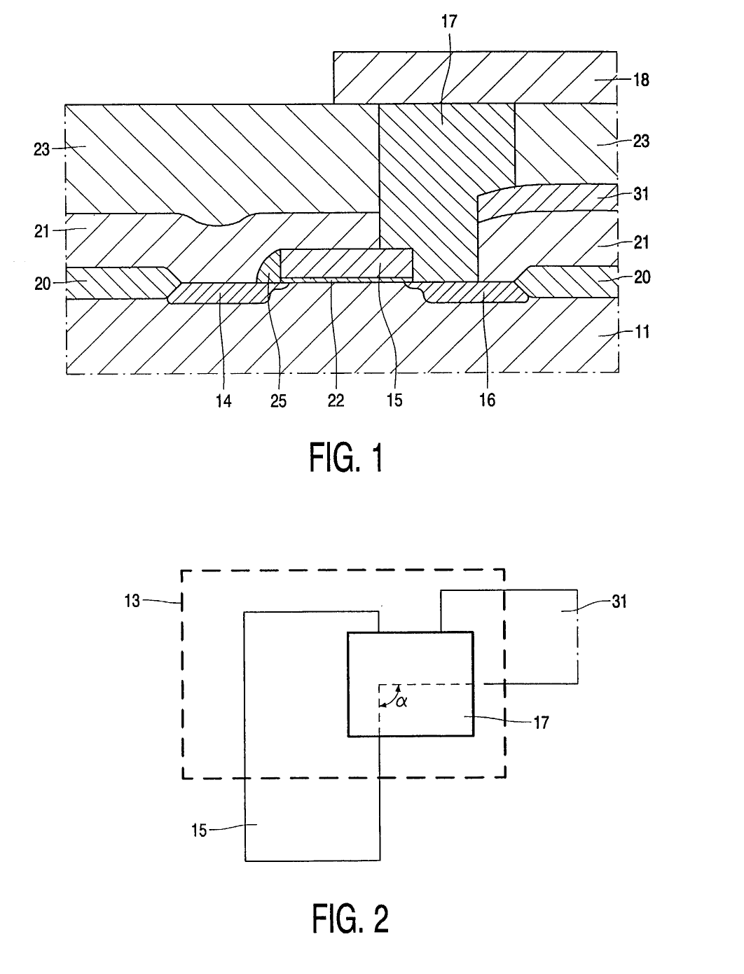

FIG. 1 shows a view in cross-section of a preferred embodiment of (a part of) an integrated circuit according to the present invention; and

FIG. 2 shows a top view of a section of FIG. 1;

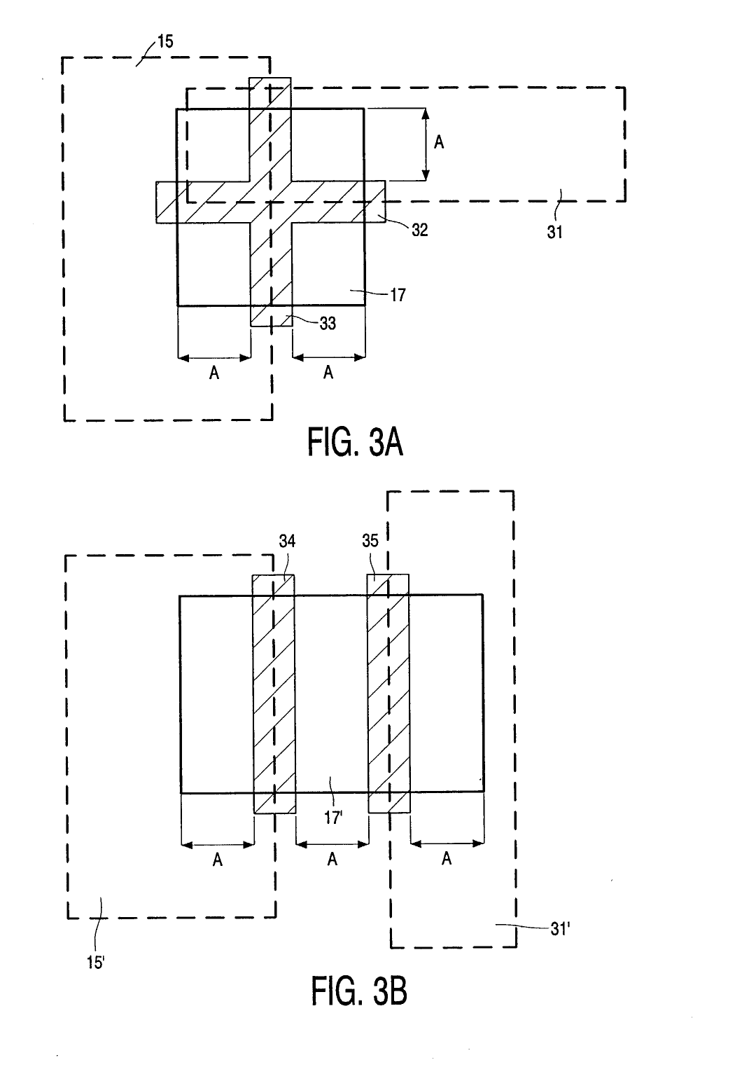

FIGS. 3A and 3B show a top view in section of a possible embodiment of the present invention and a top view in section of a prior art device resp;

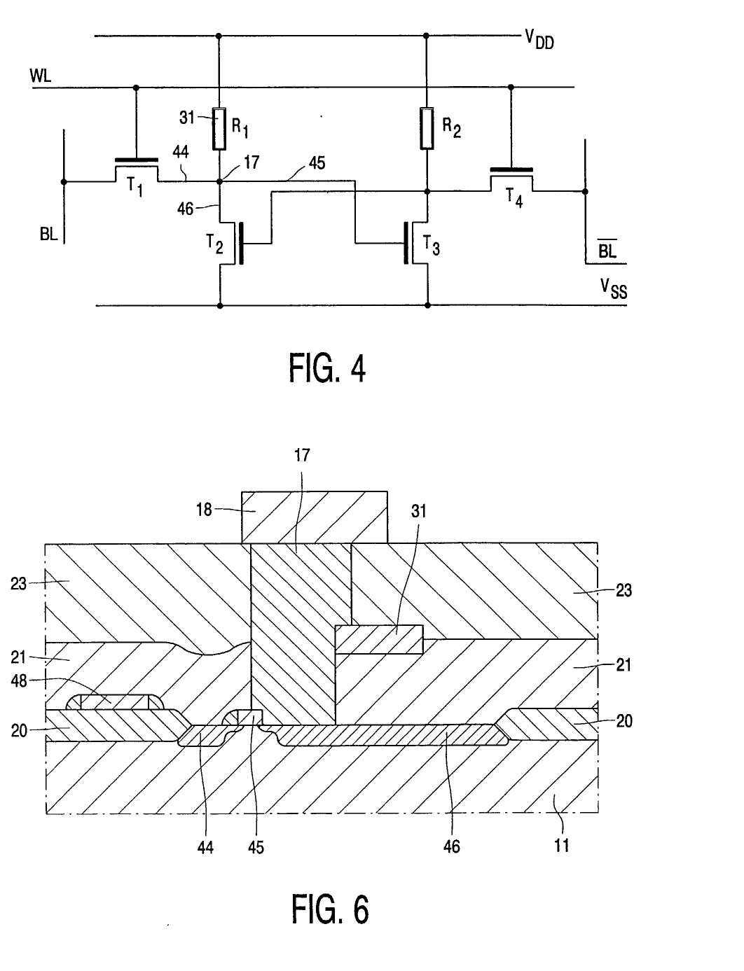

FIG. 4 shows a circuit diagram of a SRAM cell according to a preferred embodiment of the present invention.

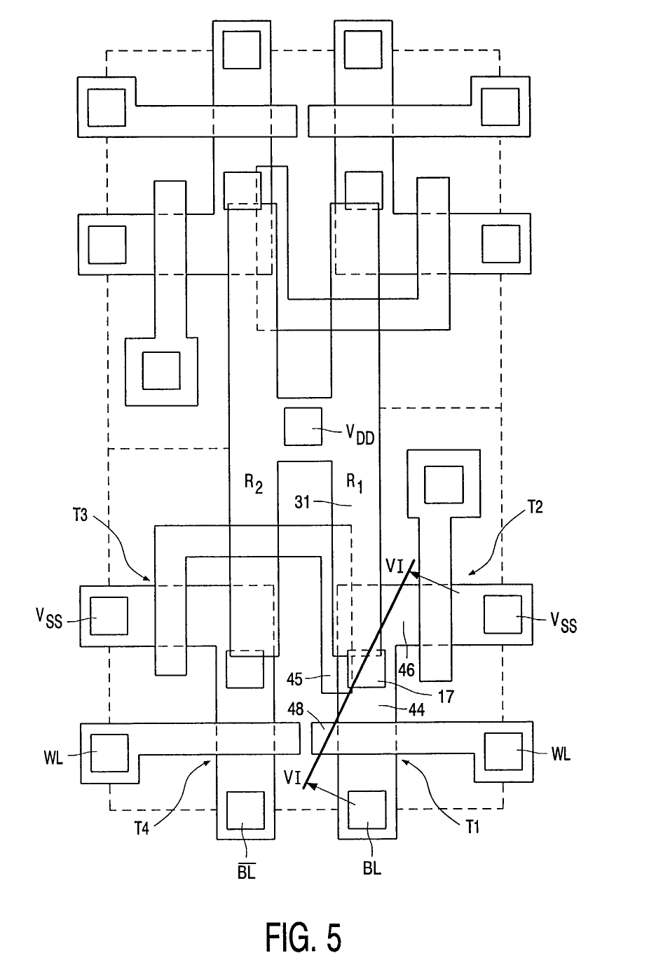

FIG. 5 shows a layout of the SRAM cell shown in FIG. 4; and

FIG. 6 shows a cross-section along the line indicated in the layout of FIG. 5.

The integrated circuit 10 (FIGS. 1 and 2) on a silicon substrate is arranged either in the substrate or in an epitaxial layer 11 which is on the substrate in which N⁺ regions 14 and 16 are defined. Then, a SiO₂ field oxide 20 is arranged to the side of regions 14 and 16 and on the epitaxial layer a gate oxide layer 22 and a gate 15 of polycrystalline silicon are arranged, an oxide film is deposited over the gate, followed by anisotropical back-etching of this film, leaving the spacer oxide 25 besides the gate. Over the structure is then deposited an oxide layer 21, also called the first Inter Layer Dielectric (ILD).

A resistive layer 31 is then arranged, for instance of polycrystalline silicon with a phosphor doping of 10¹⁶ atoms per cm³. An oxide layer 23, also called the second ILD, is then arranged thereover. Thereafter, planarisation, a plasma anisotropical contact etching step which stops on silicon or polysilicon, the filling of the contact hole with conducting material, for instance with tungsten (W), and deposition and structuring of a first metal layer, for instance aluminum, takes place.

Although the integrated circuit according to the present invention can be manufactured by means of NMOS and PMOS technology, CMOS is preferably used as this is the dominant technology for microprocessor fabrication.

In the shown preferred embodiment the layer 31 extends substantially transversely relative to the polysilicon gate 15. Thus is prevented that during etching through these layers and the insulating layers to the semi-conducting region 16 the contact with the bottom layer 15 could be insufficient. Because of the configuration wherein the layers 15 and 31 extend substantially transversely or at a considerable angle α relative to each other in a lateral dimension, which is clearly visible in the top-view (FIG. 2), the misalignment tolerances of the layers 15 and 31 are situated under the same angle, whereby the angle α is measured between the edges of the two layers that are covered by the interconnection plug 17. Thus, the area needed for the contact can be reduced. Only a relatively small portion of the layer will not be in contact with the interconnection plug, whereby the tolerances for the masks are smaller. An acceptable tolerant range is chosen such, that 99% of all the fabricated devices will operate correctly. Consequently, the misalignment tolerance is taken as the 4σ limit, where σ is the standard deviation of a Gaussian distribution of the misalignment of the relative misalignment layers. So, when there is a contact surface area of for instance 0.9×0.9 (μm)², in the case of a tolerance error of 0.2 μm, contact will still be made over a considerable part, at least 0.7 μm, between the interconnection plug and the underlying layer.

This misalignment consideration applies for the relative misalignment of the layers 17 and 15, and also that of 17 and 31. By choosing the angle α substantially different from 0° and 180°, the area overhead necessary to compensate for the misalignment can be reduced, because this way the 4 sigmas corresponding to the two layers do not add to the size in one lateral dimension.

For further illustration reference is to FIGS. 3A and 3B resp. wherein the shaded areas 32 and 33 which indicate the 4σ area partly overlap while this is not the case with the indicated 4 sigma areas 34 and 35 of layers 15′ and 31′ according to an example from the prior art. The length of the double headed arrows A gives an indication for the minimum required contact overlap to secure a sufficient contact.

From the above it will be understood that the preferred embodiment according to the present invention is particular suitable for connections where the contact area is less relevant, such as connections to high ohmic load resistors as in that case the presence of some contact area is usually sufficient.

A circuit using the arrangement according to FIGS. 1 and 2, wherein the source (or drain) and gate of a MOSFET are interconnected can be used in the field of ESD (Electro Static Discharge) protection.

The four layer contact as mentioned above can be used to reduce the size of a SRAM (Static Random Access Memory) cell by approximately 10% due to the elimination of a contact. A SRAM cell (FIG. 4) comprises transistors T₁-T₄ and resistors R₁ and R₂ which are arranged between bit lines BL and \overline{BL}, voltage levels V_{DD} and V_{SS} and a word line WL. Transistors T₂ and T₃ are connected as flipflop. Transistors T₁ and T₄ are generally referred to as select (or drive) transistors.

The four layer contact of the present invention can be introduced in the SRAM cell as the contact plug 17, connecting a high-resistance polysilicon layer 31, which is the resistor R₁, a n⁺ region 44 which forms the source of transistor T₁, a n⁺ region 46 which forms the drain of transistor T₂, and a polysilicon line 45 which forms a gate contact of transistor T₃. This is also visable in the layout (FIG. 5), which shows two identical SRAM cells containing four transistors T₁-T₄, two resistors R₁-R₂ and contacts for the wordline WL, bitlines BL, and \overline{BL} and voltage contacts V_{SS} and V_{DD}. The contact plug 17 forms a contact region for the source 44 of transistor T₁ for the drain 46 of transistor T₂ and also for the gate of transistor T₃ via the polysilicon line 45. The contact edges of the polysilicon resistor R₁ 31 and the polysilicon line 45 at the contact plug 17 are perpendicular to each other, thus forming the angle α (in this case 90°) necessary to at least reduce or minimize the area needed for the contact plug. By connecting the gate of transistor T₃ via the polysilicon line 45 directly to the contact plug 17, a gate contact of transistor T₃ can be omitted, thus reducing the area needed for the SRAM cell.

FIG. 6 shows a cross section of the contact plug 17 along the line indicated in FIG. 5. In this case, the region 46 forms the drain of transistor T₂ and the region 44 forms the source of transistor T₁. From the top view (FIG. 5), it is clear that the diffusion regions 44 and 46 are electrically connected. However, below the polysilicon line 15 there is no diffusion area, as the polysilicon prevents the implantation of ions. The metal layer 18 which is deposited on top of the contact 17 (FIG. 6) is necessary to protect the tungsten W during etching. The arrangement of the subsequent layers is the same as mentioned above.

The contact resistance will be relatively high. In case of a SRAM cell, the connection to the gate of transistor T₂ or T₃ can tolerate about 1 kOhm and the connection to the load resistor R₁ or R₂ can tolerate much more, up to MΩ as the load resistor is typically in the GΩ range.

The above described interconnection contact plug can also be applied in SRAM with TFT (Thin Film Transistors) load instead of resistors. Further details of such a circuit are for instance described in the U.S. Pat. No. 5,545,584.

The above described four-contact interconnection plug can also be applied advantageously in the arrangement of the Japanese patent application published under number JP 06-350055.

The present invention is not limited to the above described preferred embodiment thereof; the rights sought are defined by the following claims, within the scope of which many modifications can be envisaged.

1. Integrated circuit, comprising:
a substrate with a first (semi-)conductive region arranged in or on the substrate;
a second (semi-)conductive region which is isolated for at least a considerable part relative to the first region and is arranged above or adjacent to the first region;
third (semi-)conductive region which is insulated for at least a considerable part relative to the first and second (semi-)conductive regions and is arranged thereabove;
fourth (semi-)conductive region which is insulated relative to the first, second and third (semi-)conductive regions and is arranged thereabove; and
(semi-)conductive interconnection contact which mutually connects said four (semi-)conductive regions (semi-)conductively, wherein at least two of the four (semi)conductive regions extend substantially parallel to the substrate of the integrated circuit at a considerable lateral angle relative to each other.

2. integrated circuit as claimed in claim 1, wherein the second and the third region extend substantially transversely relative to each other.

3. Integrated circuit wherein the fourth region is a metal layer, the interconnection extends substantially transversely of the substrate and the metal layer and is of metal, and the first (semi-)conductive region is a part of a FET (Field Effect Transistor) embodied in CMOS (Complementary Metal Oxide Semiconductor).

4. Integrated circuit applying to claim 1 to any of claims 1, 2 or 3, wherein:
the first region is a source or drain of a MOSFET;
the second region is the gate of a said MOSFET;
the third region is a polysilicon layer showing a certain resistance value; and;
the fourth region is a metal layer.

5. Integrated circuit as claimed in any of the foregoing claims, also including a microprocessor.

6. Portable telephone provided with a (rechargeable) electric power supply and an integrated circuit as claimed in one or more of the foregoing claims.

7. A method for manufacturing an integrated circuit according to any of claims 1-5.

8. A method for manufacturing an integrated circuit according to any of claims 1-5, wherein:
source and drain regions are arranged in a semi-conductor substrate (or epitaxial layer thereof);
a gate oxide and gate are formed above the substrate in between the source and drain regions;
a first Inter Layer Dielectric (ILD) is applied over the so called MOSFET;
a resistive layer of polysilicon is deposited over the first ILD;
a second Inter Layer Dielectric is applied over the resistive layer;
a contact hole is etched, through said first and second ILD; and
the etched contact hole is filled with conducting material.

9. Integrated circuit according to any of claims 1-5, wherein:
the first (semi-)conductive layer is the source or drain of a transistor (T₁, T₂) of a SRAM cell;
the second (semi-)conductive layer is a gate of the transistor (T₃) or is connected to that gate of a SRAM cell;
the third (semi-)conductive layer is a resistor (R₁) of a SRAM cell;
the fourth (semi-)conductive layer is a metallic layer above the interconnection contact of a SRAM cell.
